(19) United States
(12) Patent Application Publication
(10) Pub. No.: US 2014/0210504 A1
(43) Pub. Date: Jul. 31, 2014

(54) TESTING DEVICE FOR ELECTRONIC DEVICE TESTING

(71) Applicant: Hon Hai Precision Industry Co., Ltd., New Taipei (TW)

(72) Inventor: SHIN-WEN CHEN, New Taipei (TW)

(73) Assignee: HON HAI PRECISION INDUSTRY CO., LTD., New Taipei (TW)

(21) Appl. No.: 13/900,569

(22) Filed: May 23, 2013

(30) Foreign Application Priority Data
Jan. 30, 2013 (CN) 2013100361823

(51) Int. Cl. G01R 1/067

(52) U.S. Cl. CPC G01R 1/06722
USPC 324/755.05

(57) ABSTRACT

A testing device includes a test board, a number of locating pins, a pin holder, a number of metal pins, a connector holder, a connector, a number of elastic elements, and a pressure block. The test board is electrically connected with a testing circuit. The locating pins are fixed on the testing board to guide the connector holder. Bottoms of the number of metal pins are vertically fixed in the pin holder. The elastic elements are arranged between the pin holder and the connector holder for pushing the connector holder back to its original position after testing. The connector is set in the connector holder and connected with an electronic device to be tested. The pressure block is positioned above the connector holder and used to push the connector holder down to the pin holder to make the testing contacts in the connector contact the metal pins.

### BACKGROUND

1. Technical Field

Embodiments of the present disclosure relate to testing devices for testing electronic devices and, particularly, to a testing device with solid metal pins.

2. Description of Related Art

Many testing devices used for electronic device testing include spring loaded metal test pins with retractable tips. When the devices or products to be tested are very small or the testing area is limited, very slim test pins are needed. Because of the complex nature of the spring loaded pin, slim test pins are very expensive and easily broken.

### BRIEF DESCRIPTION OF THE DRAWINGS

FIG. 1 is a schematic, exploded, isometric view of a testing device according to an exemplary embodiment of the present invention.

FIG. 2 is an enlarged view of a connector shown in FIG. 1.

FIG. 3 is an enlarged view of one metal pin shown in FIG. 1.

FIG. 4 is essentially an assembled view of the testing device of FIG. 1, together with a camera module under test.

### DETAILED DESCRIPTION

The disclosure, including the accompanying drawings in which like reference numerals indicate similar elements, is illustrated by way of example and not by way of limitation. It should be noted that references to “an” or “one” embodiment in this disclosure are not necessarily to the same embodiment, and such references can mean “at least one.”

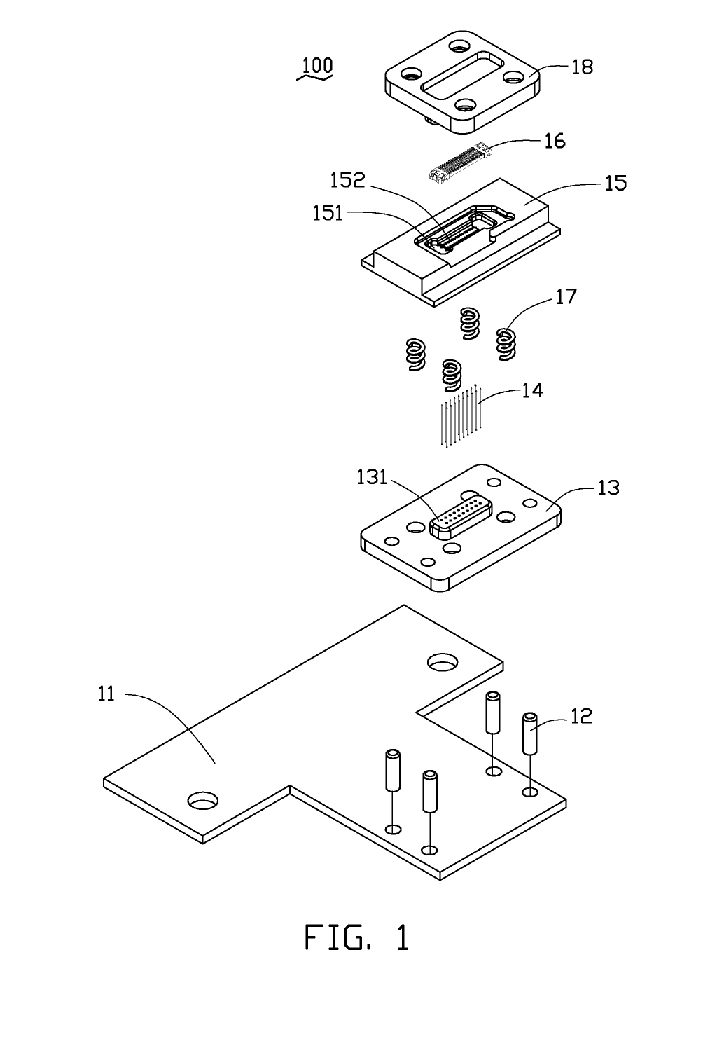

FIG. 1 is an exploded, isometric view of a testing device 100. The testing device 100 includes a testing board 11, four locating pins 12, a pin holder 13, a number of metal pins 14, a connector holder 15, a connector 16, four elastic elements 17, and a pressure block 18. The testing board 11 is electrically connected to a testing circuit (not shown), and the four locating pins 12 are vertically fixed on the testing board 11. The pin holder 13 is fixed on top ends of the four locating pins 12. The pin holder 13 includes a pin fixing block 131 arranged on the center of a main body of the pin holder 13. The bottom of each of the metal pins 14 is vertically fixed in the pin fixing block 131. Each metal pin 14 is electrically connected to a testing point in the testing board 11.

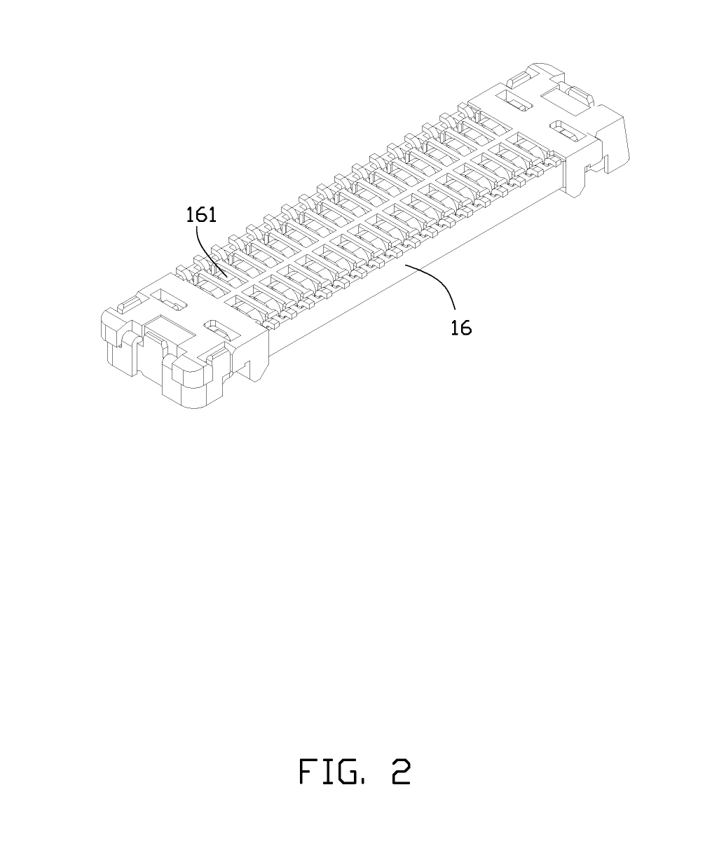

The connector holder 15 is positioned above the pin holder 13. The connector holder 15 defines four holes (not shown) corresponding to the four locating pins 12. The connector holder 15 can move along the four locating pins 12. In the top surface of the connector holder 15 corresponding to the position of the pin fixing block 131, a connector receiving slot 151 is defined and is used for receiving a connector 16. The connector 16 is connected with an electronic device to be tested. A plurality of pin holes 152 are defined in the bottom of the connector 16, below and in communication with the connector receiving slot 151. Each metal pin 14 passes through one of the pin holes 152. The connector 16 is used for electrically connecting the metal pins 14 with the electronic device to be tested. As shown in FIG. 2, the connector 16 includes a plurality of testing contacts 161 configured to contact the metal pins 14. The four elastic elements 17 are arranged between the pin holder 13 and the connector holder 15, and are configured for providing a pushing force to the connector holder 15. The pressure block 18 is arranged above the connector holder 15, for pushing the connector holder 15 down to make the metal pins 14 contact the connector holder 15.

In the embodiment, the four elastic elements 17 are four helical springs, which are arranged adjacent to the four corners of the pin fixing block 131. In other embodiments, the four helical springs 17 can be coiled around the four locating pins 12.

In the embodiment, there are four locating pins 12 and four elastic elements 17. In other embodiments, the number of locating pins 12 and the number of elastic elements 17 can be varied according to need.

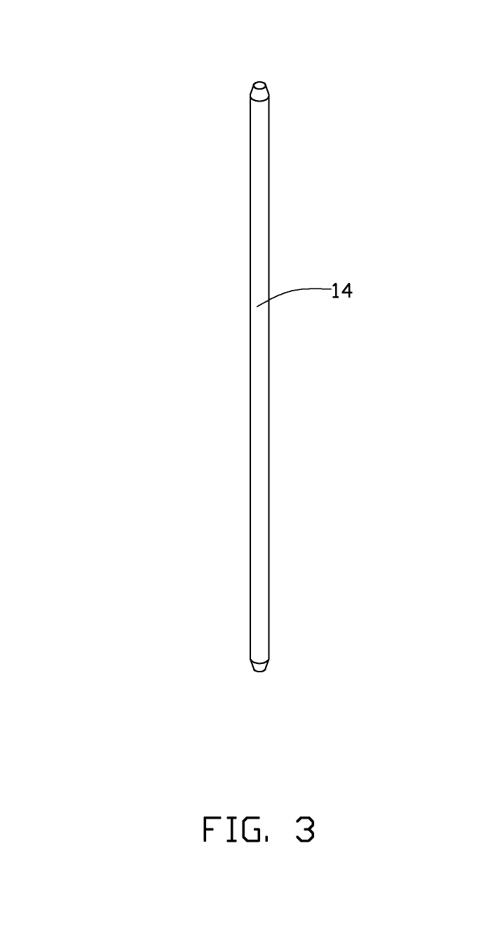

As shown in FIG. 3, the metal pins 14 are elongated and solid. In the embodiment, the metal pins 14 are made of copper alloy.

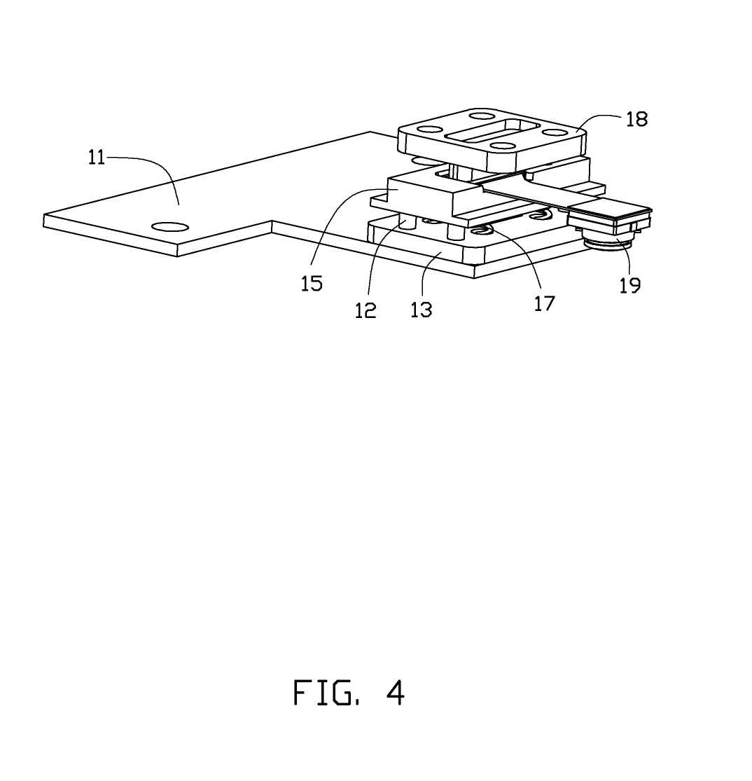

FIG. 4 is a view of a camera module 19 being tested using the testing device 100. Before testing, the connector 16 is connected to the camera module 19, and then the connector 16 is placed in the connector receiving slot 151 and the pressure block 18 is pushed down. The pressure block 18 pushes the connector holder 15 down along the locating pins 12, which compresses the elastic elements 17. The metal pins 14 pass through the pin holes 152 in the bottom of the connector receiving slot 151 and contact the testing contacts 161 of the connector 16, thereby electrically connecting the testing board 11 to the camera module 19. Then, the testing board 11 can send test signals to the camera module 19. After testing, the pressure block 18 can be lifted up, and then the connector holder 15 is pushed up to its original position by the elastic elements 17. Using solid metal pins 14 with the external elastic elements (springs) 17 simplifies the testing device 100 and reduces the risk of pin failure.

Although certain inventive embodiments have been specifically described, the present disclosure is not to be construed as being limited thereto. Various changes or modifications may be made to the present embodiments without departing from the scope and spirit of the present disclosure.

What is claimed is:

1. A testing device comprising:
a testing board configured to be electrically connected to a testing circuit;
a pin holder fixed on the testing board;
a plurality of metal pins, bottoms of the metal pins fixed in the pin holder, each of the metal pins being electrically connected with a testing point of the testing board;
a connector holder defining a plurality of pin holes, the metal pins extending through the pin holes;
a connector arranged in the connector holder, the connector comprising a plurality of testing contacts, and the connector configured to connect the metal pins and an electronic device under test via the testing contacts;
a plurality of elastic elements arranged between the pin holder and the connector holder and configured to apply a push force to the connector holder; and
a pressure block configured to push the connector holder to move toward the pin holder, thereby causing the testing contacts of the connector to contact the metal pins held by the pin holder.

2. The testing device of claim 1, further comprising a plurality of locating pins fixed on the testing board and positioned to guide the movement of the connector holder.

3. The testing device of claim 2, wherein the plurality of locating pins is four locating pins.

4. The testing device of claim 2, wherein the pin holder comprises a pin fixing block arranged on a center of a main body of the pin holder, and the bottoms of the metal pins are vertically fixed in the pin fixing block.

5. The testing device of claim 1, wherein the metal pins are made of copper alloy.

6. The testing device of claim 1, wherein a connector receiving slot is defined in a center of the connector holder, the connector is arranged in the connector receiving slot, a plurality of pin holes are defined in the bottom of the connector, below and in communication with the connector receiving slot, and the pin holes correspond to the metal pins fixed in the pin holder.

7. The testing device of claim 1, wherein the plurality of elastic elements is four elastic elements.

8. The testing device of claim 7, wherein the four elastic elements are helical springs.

9. The testing device of claim 8, further comprising four locating pins fixed on the testing board and positioned to guide the movement of the connector holder, wherein the four helical springs are coiled around the locating pins.
